(19) United States
(12) Patent Application Publication
(10) Pub. No.: US 2023/0292488 A1
(43) Pub. Date: Sep. 14, 2023

(54) SEMICONDUCTOR STRUCTURE, ARRAY STRUCTURE, MULTI-LAYER STACK STRUCTURE, AND METHOD FOR FABRICATING ARRAY STRUCTURE

(71) Applicant: CHANGXIN MEMORY TECHNOLOGIES, INC., Hefei (CN)

(72) Inventors: Guangsu SHAO, Hefei (CN); Yunsong QIU, Hefei (CN); Deyuan XIAO, Hefei (CN)

(21) Appl. No.: 17/893,183

(22) Filed: Aug. 23, 2022

Related U.S. Application Data
(63) Continuation of application No. PCT/CN2022/099714, filed on Jun. 20, 2022.

(30) Foreign Application Priority Data
Mar. 14, 2022 (CN) 202210249283.8

(51) Int. Cl. H01L 27/108

(52) U.S. Cl. CPC H01L 27/10814; H01L 27/10852; H01L 27/10873; H01L 27/10885

(57) ABSTRACT

Embodiments relate to a semiconductor structure, and an array structure and a method for fabricating same. The semiconductor structure includes: a substrate having a bit line structure therein; an active area, where an end of the active area is positioned on the bit line structure, and along a direction perpendicular to the substrate, the active area includes a first channel layer and a second channel layer wrapping at least a bottom surface and part of a sidewall of the first channel layer, and a bottom of the second channel layer is electrically connected to the bit line structure; a word line structure, where the word line structure is positioned on two opposite sides of the active area in the direction perpendicular to the substrate; and a source and a drain respectively positioned at two ends along an extension direction of the active area.

### CROSS-REFERENCE TO RELATED APPLICATION

Embodiments of the present disclosure is a continuation of PCT/CN2022/099714, filed on Jun. 20, 2022, which claims priority to Chinese Patent Application No. 202210249283.8 filed to the State Patent Intellectual Property Office on Mar. 14, 2022, the entire contents of which are incorporated herein by reference.

### TECHNICAL FIELD

Embodiments of the present disclosure relate to the field of semiconductor manufacturing, and more particularly, to a semiconductor structure, an array structure, a multi-layer stack structure, and a method for fabricating an array structure.

### BACKGROUND

Thin film transistor (TFT) can be employed to drive liquid crystal pixels on a liquid crystal display (LCD). The TFT is used in active matrix LCD, which is one of the best LCD color display devices at present, with a display effect close to a CRT display. The active matrix LCD display devices are the mainstream display devices used on notebooks and desktops. Each pixel is controlled by the TFT integrated thereon, which not only greatly increases speed, but also significantly improves contrast and brightness, and meanwhile resolution reaches a higher level.

Indium gallium zinc oxide (IGZO) is a channel layer material used in a new generation of TFT technology. A TFT transistor fabricated by using IGZO has the following advantages. First, a leakage current is lower, and thus bit storage time is longer; second, a drive current is larger, and thus a data write speed can be improved.

### SUMMARY

According to various embodiments of the present disclosure, a semiconductor structure, an array structure and a fabrication method thereof are provided to improve a breakover current of a transistor.

According to some embodiments, the embodiments of the present disclosure provide a semiconductor structure, which includes: a substrate having a bit line structure therein, an active area, a word line structure, and a source and a drain. An end of the active area is positioned on the bit line structure, and along a direction perpendicular to the substrate, the active area includes a first channel layer and a second channel layer wrapping at least a bottom surface and part of a sidewall of the first channel layer, where a bottom of the second channel layer is electrically connected to the bit line structure. The word line structure is respectively positioned on two opposite sides of the active area in the direction perpendicular to the substrate. The source and the drain are respectively positioned at two ends along an extension direction of the active area.

According to some embodiments, the embodiments of the present disclosure further disclose a method for fabricating an array structure. The method includes: providing a substrate; forming a plurality of bit line structures extending along a first direction in the substrate; forming a first dielectric layer on the substrate and forming active areas arranged in an array in the first dielectric layer, where an end of a given one of the active areas is positioned on the bit line structure, and in a direction perpendicular to the substrate, the given active area includes a first channel layer and a second channel layer wrapping at least a bottom surface and part of a sidewall of the first channel layer, and a bottom of the second channel layer is electrically connected to the bit line structure; forming multiple second dielectric layers extending along a second direction in the first dielectric layer, where the second direction intersects the first direction, and each of the multiple second dielectric layers is positioned between two adjacent columns of active areas; and forming a word line structure, where the word line structure is respectively positioned on two opposite sides of the given active area.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic cross-sectional structural diagram of a semiconductor structure in an embodiment according to embodiments of the present disclosure;

FIG. 2 is a schematic three-dimensional (3D) structural diagram of an array structure in an embodiment according to the embodiments of the present disclosure;

FIG. 3 is a schematic cross-sectional structural diagram obtained by cutting along a direction AA′ in FIG. 2;

FIG. 4 is a flow block diagram of a method for fabricating an array structure in an embodiment according to the embodiments of the present disclosure;

FIG. 5 is a schematic 3D structural diagram of a substrate in an embodiment according to the embodiments of the present disclosure;

FIG. 6 is a schematic 3D structural diagram after formation of a bit line trench in an embodiment according to the embodiments of the present disclosure;

FIG. 7 is a schematic 3D structural diagram after formation of a bit line structure in an embodiment according to the embodiments of the present disclosure;

FIG. 8 is a schematic 3D structural diagram after formation of a first dielectric layer in an embodiment according to the embodiments of the present disclosure;

FIG. 9 is a schematic 3D structural diagram after forming a through hole in the first dielectric layer in an embodiment according to the embodiments of the present disclosure;

FIG. 10 is a schematic 3D structural diagram after formation of a first channel layer in an embodiment according to the embodiments of the present disclosure;

FIG. 11 is a schematic 3D structural diagram after formation of a second channel layer in an embodiment according to the embodiments of the present disclosure;

FIG. 12 is a schematic 3D structural diagram after forming an opening in the first dielectric layer in an embodiment according to the embodiments of the present disclosure;

FIG. 13 is a schematic 3D structural diagram after formation of a second dielectric layer in an embodiment according to the embodiments of the present disclosure;

FIG. 14 is a schematic 3D structural diagram after reducing a thickness of the first dielectric layer in an embodiment according to the embodiments of the present disclosure;

FIG. 15 is a schematic 3D structural diagram after formation of a gate oxide layer in an embodiment according to the embodiments of the present disclosure;

FIG. 16 is a schematic 3D structural diagram after formation of a word line conductive layer in an embodiment according to the embodiments of the present disclosure; and

FIG. 17 is a schematic 3D structural diagram after forming the first dielectric layer on a surface of the word line conductive layer in an embodiment according to the embodiments of the present disclosure.

### DETAILED DESCRIPTION

For ease of understanding the embodiments of the present disclosure, the embodiments of the present disclosure will be described more fully hereinafter with reference to the accompanying drawings. Some embodiments among the embodiments of the present disclosure are provided in the accompanying drawings. However, the embodiments of the present disclosure may be embodied in many different forms and should not be limited to the embodiments set forth herein. Rather, these embodiments are provided such that disclosed contents of the embodiments of the present disclosure will be more thorough and complete.

Unless otherwise defined, all technical and scientific terms employed herein have the same meaning as commonly understood by those skilled in the art to which the embodiments of the present disclosure belong. The terms employed in the specification of the embodiments of the present disclosure are merely for the purpose of describing some embodiments and are not intended for limiting the embodiments of the present disclosure. As used herein, the term “and/or” includes any and all combinations of one or more of the associated listed items.

It should be understood that when an element or layer is referred to as being “on”, “connected to” or “coupled to” other elements or layers, it may be directly on, connected or coupled to the other elements or layers, or intervening elements or layers may be present. In contrast, when an element is referred to as being “directly on”, “directly connected to” or “directly coupled to” other elements or layers, there are no intervening elements or layers present. It should be understood that although the terms first, second, third, etc. may be employed to describe various elements, components, regions, layers and/or sections, these elements, components, regions, layers and/or sections should not be limited by these terms. These terms are only employed to distinguish one element, component, region, layer or section from another element, component, region, layer or section. Therefore, without departing from the teachings of the present disclosure, a first element, component, region, layer or section discussed below may be represented as a second element, component, region, layer or section.

Spatially relative terms such as “below”, “under”, “lower”, “beneath”, “above”, “upper” and the like may be used herein for ease of description to describe relationships between one element or feature as shown in the figures and another element(s) or feature(s). It should be understood that the spatially relative terms may be intended to encompass different orientations of the device in use or operation in addition to the orientation depicted in the figures. For example, if the device in the figures is turned over, elements or features described as “under”, “beneath” or “below” other elements would then be oriented “above” the other elements or features. Thus, the exemplary term “under”, “below” or “beneath” may encompass both an orientation of above and below. The device may be otherwise oriented (rotated 90 degrees or at other orientations) and the spatially relative descriptors used herein should be interpreted accordingly.

The terminology used herein is for the purpose of describing some embodiments only and is not intended to limit the embodiments of the present disclosure. As used herein, the singular forms of “a”, “one” and “said/the” are also intended to include plural forms, unless the context clearly indicates otherwise. It should also be understood that the terms “comprising” and/or “including”, when used in this specification, determine the presence of the described features, integers, steps, operations, elements and/or components, but do not preclude the presence or addition of one or more other features, integers, steps, operations, elements, components, and/or groups thereof. As used herein, the term “and/or” includes any and all combinations of related listed items.

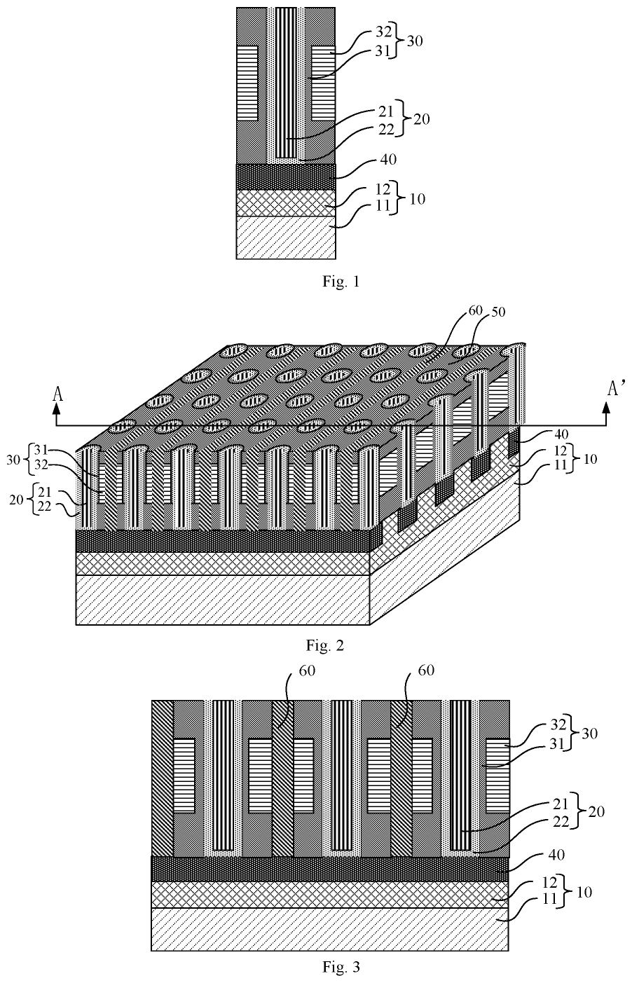

Reference is made to FIG. 1 to FIG. 17. It should be noted that the illustrations provided in the embodiments merely illustrate the basic idea of the embodiments of the present disclosure in a schematic manner. Although only the components related to the embodiments of the present disclosure are shown in the drawings rather than the number, shape and dimensional drawing of components in actual implementation. The form, number and proportion of each component in actual implementation may be a random change, and the component layout form may be more complicated.

As shown in FIG. 1, an embodiment of the present disclosure discloses a semiconductor structure, including: a substrate 10 having a bit line structure 40 in the substrate 10, an active area 20, a word line structure 30, and a source and a drain. An end of the active area 20 is positioned on the bit line structure 40, and along a direction perpendicular to the substrate 10, the active area 20 includes a first channel layer 21 and a second channel layer 22 wrapping at least a bottom surface and part of a sidewall of the first channel layer 21, where a bottom of the second channel layer 22 is electrically connected to the bit line structure 40. The word line structure 30 is respectively positioned on two opposite sides of the active area 20 in the direction perpendicular to the substrate 10. The source and the drain are respectively positioned at two ends along an extension direction of the active area 20.

For example, the substrate 10 may include a base substrate 11 and a base substrate dielectric layer 12 positioned on a surface of the base substrate 11, where the base substrate 11 may include, but is not limited to, a silicon substrate 11, a silicon carbide substrate 11, or other base substrate 11. The base substrate dielectric layer 12 may include, but is not limited to, a silicon oxide layer. The bit line structure 40 is positioned in the base substrate dielectric layer 12. The bit line structure 40 may include, but is not limited to, a metal layer.

An end of the active area 20 is positioned on the bit line structure 40, and the active area 20 extends along a direction perpendicular to the substrate 10. The active area 20 includes a first channel layer 21 and a second channel layer 22 wrappings at least a bottom surface and part of a sidewall of the first channel layer 21, and a bottom of the second channel layer 22 is electrically connected to the bit line structure 40. For example, the first channel layer 21 and/or the second channel layer 22 includes at least one of indium oxide, gallium oxide, zinc oxide, indium gallium oxide, indium zinc oxide, gallium zinc oxide, and indium gallium zinc oxide.

In some embodiments, both the first channel layer 21 and the second channel layer 22 are indium gallium zinc oxide (IGZO) layers, where the first channel layer 21 is a high-resistance IGZO layer, and the second channel layer 22 is a low-resistance IGZO layer. Compared with a conventional active area material, using the IGZO as the active area material can increase a drive current of a transistor and improve a write speed. When the transistor is turned off, a leakage current is lower and bit duration is longer. In addition, the low-resistance IGZO layer has fewer material defects, which can significantly improve an on/off ratio and a threshold voltage for the transistor. In addition, a high-quality homojunction interface can be formed between the low-resistance IGZO layer and the high-resistance IGZO layer, which can further improve the on/off ratio and the threshold voltage for the transistor and reduce the leakage current. In some embodiments, a thickness of the first channel layer 21 may be 10 nm or less, for example, 10 nm, 8 nm, 5 nm, or 3 nm.

Still referring to FIG. 1, the word line structure 30 is respectively positioned on two opposite sides of the active area 20 in a direction perpendicular to the substrate 10. The word line structure 30 includes a gate oxide layer 31 and a word line conductive layer 32 positioned on an outer side of the gate oxide layer 31. For example, the gate oxide layer 31 may include, but is not limited to, a silicon dioxide layer, and the word line conductive layer 32 may be a metal layer, such as a copper layer. The source and the drain are positioned at two ends along an extension direction of the active area 20, and a channel region is provided between the source and the drain. For example, a position of the word line conductive layer 32 corresponds to a position of the channel region.

In some embodiments, the active area 20 is of a columnar structure, such as cylindrical or cuboid. The gate oxide layer 31 surrounds and covers an outer sidewall of the active area 20 and separates the active area 20 from the word line conductive layer 32.

In some embodiments, other end of the active area 20 is connected to one electrode of a capacitor structure. For example, the capacitor structure includes a bottom electrode, a capacitor dielectric layer, and a top electrode that are stacked in sequence from bottom to top. As an example, the source of the semiconductor structure is connected to the bottom electrode of the capacitor structure, and the drain of the semiconductor structure is electrically connected to the bit line structure. By applying a high level to the word line conductive layer 32, a current may be formed in the channel region of the active area 20, such that the capacitor structure is electrically connected to the bit line structure 40 by means of the active area 20. In this way, data may be read from the capacitor structure, or data may be written into the capacitor structure.

For example, the foregoing semiconductor structure may be applied to a dynamic random access memory (DRAM) memory cell, to increase the drive current and the threshold voltage for the DRAM memory cell and reduce the leakage current.

As shown in FIG. 2, one of the embodiments of the present disclosure further discloses an array structure, including a plurality of semiconductor structures in any one of the foregoing embodiments. The array structure has a plurality of rows and a plurality of columns. Bit line structures 40 of the semiconductor structures positioned in the same row are electrically connected to each other; and word line structures 30 of the semiconductor structures positioned in the same column are electrically connected to each other.

FIG. 3 is a schematic cross-sectional structural diagram taken along a direction AA′ of the structure shown in FIG. 2. The bit line structures 40 of the semiconductor structures positioned in the same row are electrically connected to each other and extend along a first direction, where the first direction is a row direction of the array structure. For example, a second dielectric layer 60 is provided between the semiconductor structures positioned in the same row, and the second dielectric layer 60 separates the semiconductor structures in the same row. As can be learned with reference to FIG. 2, two adjacent columns of semiconductor structures are separated by the second dielectric layer 60. As an example, the second dielectric layer 60 may include, but is not limited to, a silicon nitride layer, a silicon oxynitride layer, or a carbon layer.

Still referring to FIG. 2, the word line structures 30 of the semiconductor structures positioned in the same column are electrically connected to each other. In addition, a first dielectric layer 50 is provided between the semiconductor structures positioned in the same column, and the first dielectric layer 50 separates active areas 20 of the semiconductor structures in the same column. For example, the first dielectric layer 50 may be a high-k dielectric material layer, such as a silicon dioxide layer.

In some embodiments, the array structure further includes a plurality of capacitor structures (not shown in the figure) arranged in an array, and the capacitor structures are connected to the active areas 20 in a one-to-one correspondence. For example, the capacitor structure includes a bottom electrode, a capacitor dielectric layer, and a top electrode that are stacked in sequence from bottom to top. A top of the active area 20 is connected to the bottom electrode.

In some embodiments, the top electrodes of the capacitor structures are connected to each other, the capacitor dielectric layers of the capacitor structures are connected to each other, and the bottom electrodes of the capacitor structures are separated by the capacitor dielectric layer. By applying a high level to the word line conductive layer 32, a breakover current may be produced in the active area 20, allowing the capacitor structure to be electrically connected to the bit line structure 40 through the active area 20, such that data can be read from the capacitor structure or data can be written to the capacitor structure.

In some embodiments, each active area 20 in the array structure includes a first channel layer 21 and a second channel layer 22 wrapping at least a bottom surface and part of a sidewall of the first channel layer 21, where the first channel layer 21 is a high-resistance IGZO layer, and the second channel layer 22 is a low-resistance IGZO layer. Due to fewer material defects of the low-resistance IGZO layer, the drive current and the threshold voltage of the transistor can be significantly improved, and the leakage current can be reduced. The high-resistance IGZO layer is positioned on the low-resistance IGZO layer, such that a high-quality homojunction interface can be formed between the high-resistance IGZO layer and the low-resistance IGZO layer, thereby further improving the on/off ratio and the threshold voltage for the transistor and reducing the leakage current.

For example, the foregoing array structure may be applied to a DRAM memory array.

One of the embodiments of the present disclosure further discloses a multi-layer stack structure, including multiple layers of array structures in any one of the foregoing embodiments. The multiple layers of array structures are stacked up and down, where the word line structures 30, the bit line structures 40 and the active areas 20 between the multiple layers of array structures are independent of each other.

For example, by taking an example where the array structure is a DRAM memory array, a 3D stack DRAM may be obtained by stacking the multiple layers of array structures. The active area 20 is jointly formed by the low-resistance IGZO layer and the high-resistance IGZO layer, such that the leakage current of a single DRAM memory cell is reduced, and on the whole, the leakage current of the 3D stack DRAM is also greatly reduced, thereby reducing power consumption caused by the leakage current, which is advantageous to ensuring normal operation of the memory cell and improving storage density.

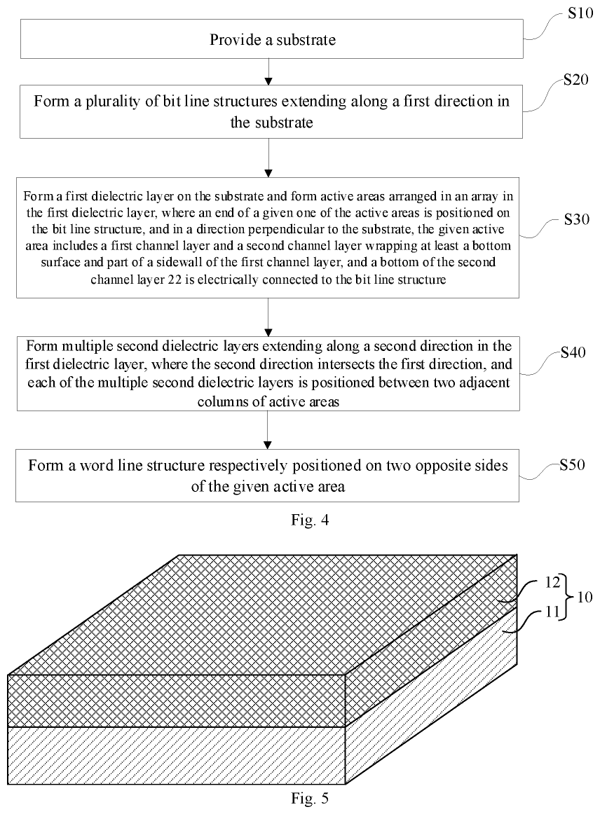

As shown in FIG. 4, one of the embodiments of the present disclosure further discloses a method for fabricating an array structure, including:
S10: providing a substrate;
S20: forming a plurality of bit line structures extending along a first direction in the substrate;
S30: forming a first dielectric layer on the substrate and forming active areas arranged in an array in the first dielectric layer, where an end of a given one of the active areas is positioned on the bit line structure, and in a direction perpendicular to the substrate, the given active area includes a first channel layer and a second channel layer wrapping at least a bottom surface and part of a sidewall of the first channel layer, and a bottom of the second channel layer 22 is electrically connected to the bit line structure;
S40: forming multiple second dielectric layers extending along a second direction in the first dielectric layer, where the second direction intersects the first direction, and each of the multiple second dielectric layers is positioned between two adjacent columns of active areas; and
S50: forming a word line structure respectively positioned on two opposite sides of the given active area.

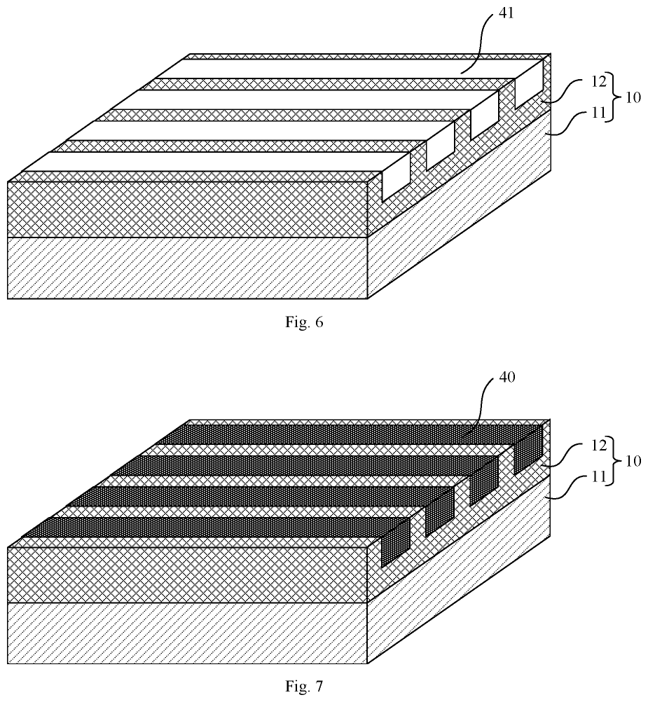

In FIG. 5, referring to Step S10, the substrate 10 provided may include a base substrate 11 and a base substrate dielectric layer 12 on a surface of the base substrate 11, as shown in FIG. 5. The base substrate 11 may include, but is not limited to, a silicon substrate 11, a silicon carbide substrate 11 or other base substrate 11. The base substrate dielectric layer 12 may include, but is not limited to, a silicon oxide layer.

In Step S20, referring to FIGS. 6 to 7, a plurality of bit line structures 40 extending along the first direction are formed in the substrate 10.

For example, as shown in FIG. 6, the base substrate dielectric layer 12 may be etched first to form bit line trenches 41 extending along the first direction in the base substrate dielectric layer 12, where the bit line trenches 41 are arranged at intervals in parallel. The process of forming the bit line trench 41 may be a dry etching process or wet etching process.

After the bit line trench 41 is formed, a metal layer is deposited in the bit line trench 41 to form the bit line structure 40. In some embodiments, the top surface of the bit line structure 40 is flush with that of the substrate 10, as shown in FIG. 7. The metal layer may be a metal conductive material with lower resistivity, and may include, but is not limited to, W (tungsten), molybdenum (Mo), Ti (titanium), Cu (copper), or Au (gold). As an example, the metal layer may be formed in the bit line trench 41 by means of a chemical vapor deposition process, and the formed metal layer fills up the bit line trench 41.

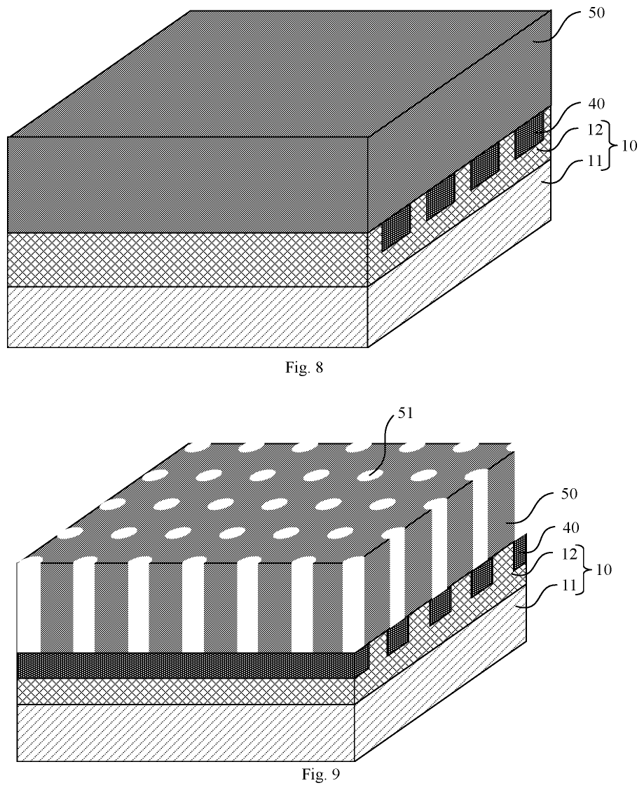

In Step S30, referring to FIGS. 8 to 11, the step of forming a first dielectric layer 50 on the substrate 10 and forming active areas 20 arranged in an array in the first dielectric layer 50 includes:
S31: forming the first dielectric layer 50 on an upper surface of the substrate 10, as shown in FIG. 8.

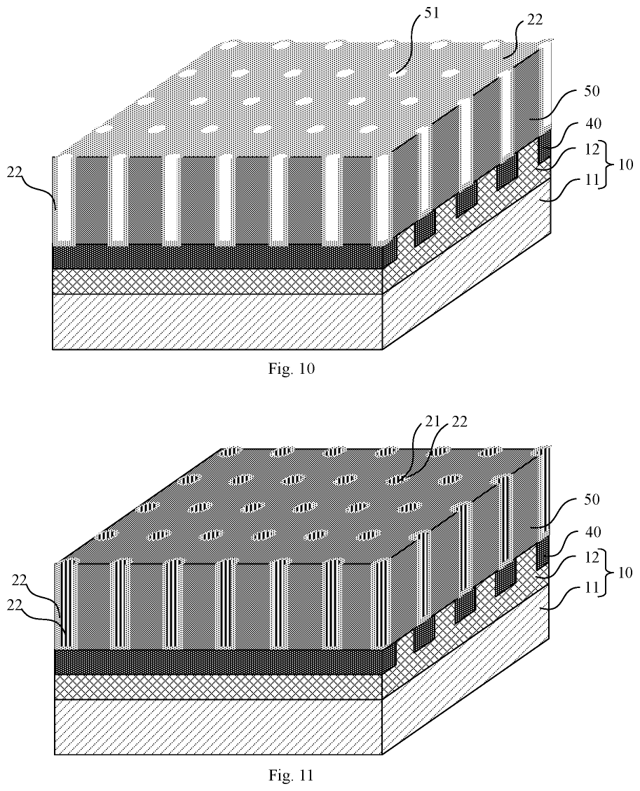

For example, the silicon oxide layer may be deposited on the upper surface of the substrate 10 by means of a deposition process to serve as the first dielectric layer 50. The deposition process may include, but is not limited to, an atomic layer deposition process, a plasma deposition process, a chemical vapor deposition process, or a physical vapor deposition process. In some embodiments, after the first dielectric layer 50 is formed through deposition, an upper surface of the first dielectric layer 50 may be polished by means of a chemical mechanical polishing (CMP) process to form a smooth and flat surface.
S32: forming through holes 51 arranged in an array in the first dielectric layer 50, where the through holes 51 is positioned above the bit line structure 40, and exposes an upper surface of the bit line structure 40, as shown in FIG. 9.

For example, a patterned photoresist layer may be first formed on the upper surface of the first dielectric layer 50, and the patterned photoresist layer may be configured to define a position and a size of one of the through holes 51. Next, the first dielectric layer 50 is etched based on the patterned photoresist layer by means of a photolithography process until an upper surface of the bit line structure 40 is exposed, such that the through holes 51 arranged in an array as shown in FIG. 9 are obtained.

In some embodiments, a hard mask layer is also formed between the patterned photoresist layer and the first dielectric layer 50. For example, a material for forming the hard mask layer may include, but is not limited to, a silicon nitride layer. After the through holes 51 are formed, the patterned photoresist layer and the hard mask layer are removed by means of the CMP process to obtain a structure as shown in FIG. 9.
S33: forming the first channel layer 21 and the second channel layer 22 in the through hole 51, where the second channel layer 22 wraps at least the bottom surface and part of the sidewall of the first channel layer 21, and the bottom of the second channel layer 22 is electrically connected to the bit line structure 40.

In some embodiments, the step of forming the first channel layer 21 and the second channel layer 22 includes:
S331: forming the second channel layer 22, where the second channel layer 22 covers a sidewall and a bottom of the through hole 51 and an upper surface of the first dielectric layer 50, as shown in FIG. 10.

The second channel layer 22 may include at least one of indium oxide, gallium oxide, zinc oxide, indium gallium oxide, indium zinc oxide, gallium zinc oxide, and IGZO.

As an example, the second channel layer 22 may be a low-resistance IGZO layer. For example, the low-resistance IGZO layer may be formed on the sidewall and the bottom of the through hole 51 and the upper surface of the first dielectric layer 50 by means of an in-situ deposition method in an oxygen atmosphere, to serve as the second channel layer 22, as shown in FIG. 10. Through the foregoing process method, a continuous low-resistance IGZO layer with a smooth surface may be formed. Compared with the conventional IGZO layer, this low-resistance IGZO layer has significantly reduced material defects, which is advantageous to improving the breakover current and the threshold voltage for a semiconductor device and reducing the leakage current.
S332: forming the first channel layer 21, where the first channel layer 21 covers a surface of the second channel layer 22 and fills up the through hole 51.

For example, the first channel layer 21 includes at least one of indium oxide, gallium oxide, zinc oxide, indium gallium oxide, indium zinc oxide, gallium zinc oxide, and IGZO.

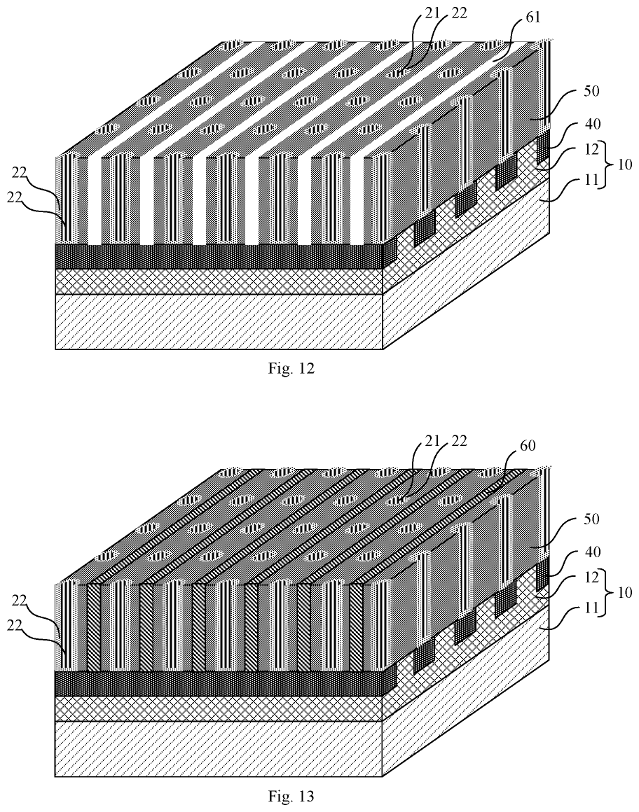

As an example, the first channel layer 21 may be a high-resistance IGZO layer. For example, a high-resistance IGZO layer may be deposited on a surface of the second channel layer 22 by means of an atomic layer deposition process in an oxygen-free atmosphere, where the high-resistance IGZO layer fills up the through hole 51. Through the foregoing process method, a high-quality homojunction interface may be formed between the low-resistance IGZO layer and the high-resistance IGZO layer, thereby greatly improving the on/off ratio and the threshold voltage for the semiconductor structure (such as a transistor).
S333: removing the first channel layer 21 and the second channel layer 22 on the upper surface of the first dielectric layer 50 to obtain the structure as shown in FIG. 11.

For example, the first channel layer 21 and the second channel layer 22 on the upper surface of the first dielectric layer 50 may be removed by means of the CMP process to expose the upper surface of the first dielectric layer 50, thereby obtaining the active area 20 comprising the first channel layer 21 and the second channel layer 22. A bottom of the second channel layer 22 is electrically connected to the bit line structure 40. In some embodiments, a top of the second channel layer 22 may be lower than the upper surface of the first dielectric layer 50, and the second channel layer 22 covers the bottom and part of the sidewall of the first channel layer 21.

In Step S40, reference is made to FIG. 12 and FIG. 13. Multiple second dielectric layers 60 extending along the second direction are formed in the first dielectric layer 50, where the second direction intersects the first direction, and each of the multiple second dielectric layers 60 is positioned between two adjacent columns of active areas 20. The step of forming the second dielectric layer 60 includes:
S41: forming multiple openings 61 extending along the second direction in the first dielectric layer 50, where each of the multiple openings 61 penetrates through the first dielectric layer 50 and exposes an upper surface of the substrate 10, as shown in FIG. 12.

For example, the second direction is the same as a column direction of the array structure. The second direction intersects the first direction. In some embodiments, the second direction is perpendicular to the first direction. As an example, the opening 61 may be a word line isolation trench.
S42: forming the second dielectric layer 60, where the second dielectric layer 60 fills up the opening 61, and an upper surface of the second dielectric layer 60 is flush with that of the first dielectric layer 50, as shown in FIG. 13.

For example, a silicon nitride layer, a silicon oxynitride layer or a carbon layer may be deposited into the opening 61 to form the second dielectric layer 60. In some embodiments, the upper surface of the second dielectric layer 60 is flush with that of the first dielectric layer 50. The second dielectric layer 60 can divide the active areas 20 in the array structure into multiple columns, where the active areas 20 in the same column are separated by the first dielectric layer 50. As an example, a process for forming the second dielectric layer 60 may include the atomic layer deposition process, the plasma deposition process, the chemical vapor deposition process, or the physical vapor deposition process. A particular process method may be determined according to a size of a device and a depth-to-width ratio of the opening 61, which is not limited in the embodiments of the present disclosure. The second dielectric layer 60 may be used as a word line isolation structure to isolate the word line structures of the semiconductor structures in two adjacent columns.

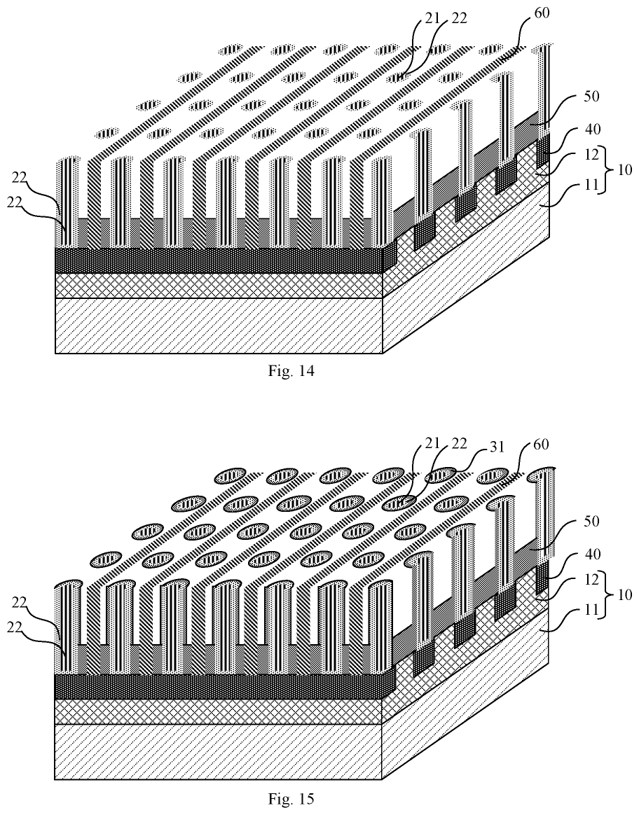

In Step S50, the step of forming the word line structure 30 includes:
S51: reducing a thickness of the first dielectric layer 50 to expose part of the sidewall of the active area 20 and part of the sidewall of the second dielectric layer 60, as shown in FIG. 14.

For example, part of the first dielectric layer 50 may be removed by means of an etching process to reduce the thickness of the first dielectric layer 50, thereby exposing the channel region of the active area 20. For example, the first dielectric layer 50 is a silicon dioxide layer. The silicon oxide layer is removed by a certain thickness by means of dry etching or wet etching to expose the channel region of the active area 20 and part of the sidewall of the second dielectric layer 60.
S52: forming a gate oxide layer 31 covering the exposed sidewall of the active area 20, as shown in FIG. 15.

For example, a silicon oxide layer may be grown on the exposed sidewall of the active area 20 by means of an atomic layer deposition process, where the silicon oxide layer wraps around the sidewall of the active area 20 to form the gate oxide layer 31.

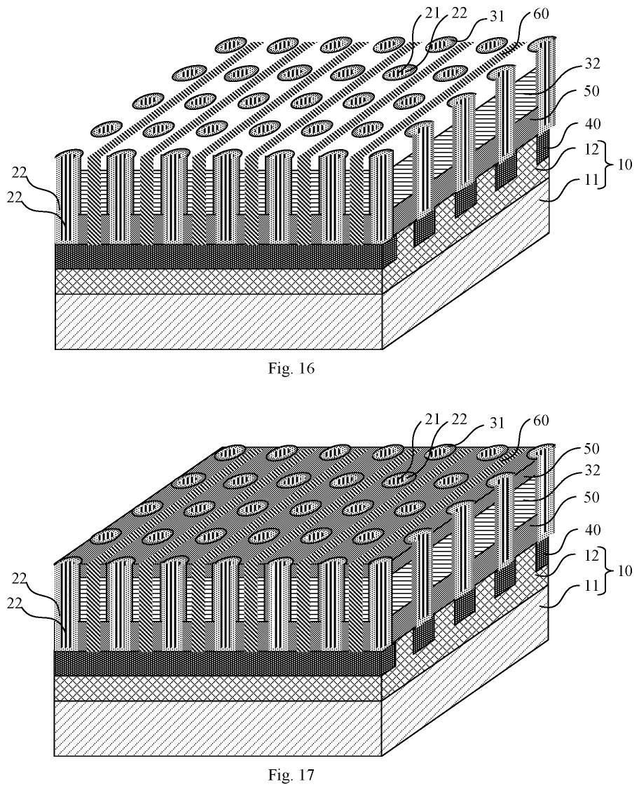

In some embodiments, when reducing the thickness of the first dielectric layer 50, a mask layer may be provided to cover the upper surface of the active area 20 and part of the first dielectric layer 50 adjacent to the active area 20, thereby protecting the first dielectric layer 50 on the sidewall of the active area 20 against removal, to serve as the gate oxide layer 31.
S53: forming a word line conductive layer 32 on an upper surface of the first dielectric layer 50, where an upper surface of the word line conductive layer 32 is lower than an upper surface of the gate oxide layer 31, as shown in FIG. 16.

For example, a conductive material layer may be deposited on the upper surface of the first dielectric layer 50, and then the thickness of the conductive material layer may be reduced until it is lower than the upper surface of the gate oxide layer 31, to obtain the word line conductive layer 32. For example, the conductive material layer may include, but is not limited to, W (tungsten), molybdenum (Mo), Ti (titanium), Cu (copper), or Au (gold). The conductive material layer may be formed on the upper surface of the first dielectric layer 50 by means of the chemical vapor deposition process.

The second dielectric layer 60 serves as the word line isolation structure to separate the word line conductive layers 32 of the semiconductor structures in two adjacent columns, such that the active areas 20 in the same column share the same word line conductive layer 32. In some embodiments, the word line conductive layer 32 is arranged around the channel region of the active area 20, which can greatly improve gate control capability.
S54: forming a first dielectric layer 50 on the upper surface of the word line conductive layer 32, where the upper surface of the first dielectric layer 50 is flush with that of the active area 20, as shown in FIG. 17.

For example, a silicon oxide layer may be deposited on the upper surface of the word line conductive layer 32 to cover the upper surface of the word line conductive layer 32, such that the thickness of the silicon oxide layer is further increased until the upper surface of the active area 20 is covered. Next, the silicon oxide layer is polished by means of the CMP process until the upper surface of the active area 20 is exposed, to obtain the first dielectric layer 50 as shown in FIG. 17. For example, a process for depositing the silicon oxide layer may include the atomic layer deposition process, the plasma deposition process, the chemical vapor deposition process, or the physical vapor deposition process.

In some embodiments, after forming the word line structure 30, the method further includes:
S60: forming a capacitor structure, where one electrode in the capacitor structure is connected to the other end of the active area 20.

For example, capacitor structures arranged in an array may be formed above the structure obtained, and the capacitor structures are connected to the active areas 20 in a one-to-one correspondence. In some embodiments, the capacitor structure includes a bottom electrode, a capacitor dielectric layer and a top electrode stacked in sequence from bottom to top.

As an example, steps of fabricating the bottom electrode of the capacitor may include:
S61: forming a bottom electrode material layer.

For example, the bottom electrode material layer is first deposited on the upper surface of the structure as shown in FIG. 17, where the bottom electrode material layer covers the upper surface of each active area 20. As an example, the bottom electrode material layer may include, but is not limited to, a tungsten layer, a titanium nitride layer, or other conductive layers. A method for depositing the bottom electrode material layer may include the atomic layer deposition process, the plasma deposition process, the chemical vapor deposition process, or the physical vapor deposition process.
S62: cutting the bottom electrode material layer along the first direction and the second direction respectively to obtain multiple bottom electrodes arranged in an array, where the bottom electrodes are in a one-to-one correspondence with the active areas 20.

For example, a mask layer may be first formed on an upper surface of the bottom electrode material layer, where the mask layer may be a silicon oxide layer or a silicon oxynitride layer. For example, the mask layer may be formed by means of the atomic layer deposition process, the plasma deposition process, the chemical vapor deposition process, or the physical vapor deposition process. Next, a patterned photoresist layer is formed on an upper surface of the mask layer, and the mask layer and the bottom electrode material layer are etched based on the patterned photoresist layer to obtain the multiple bottom electrodes arranged in an array. The patterned photoresist layer may be configured to define a position where the bottom electrode material layer needs to be segmented.

After the bottom electrodes are formed, a capacitor dielectric layer and a top electrode are formed in sequence on the upper surface of the structure obtained, where the capacitor dielectric layer covers each of the bottom electrodes, and the top electrode is positioned on an upper surface of the capacitor dielectric layer. For example, a material of the top electrode may be the same as a material of the bottom electrode, for example, a tungsten layer, a titanium nitride layer, or other conductive layers.

In the array structure fabricated by means of the foregoing method for fabricating an array structure, the active area includes a first channel layer and a second channel layer, and a high-quality homojunction interface formed between the first channel layer and the second channel layer can increase the on/off ratio and the threshold voltage for the transistor, reduce the leakage current, reduce heat emitted per unit area from the array structure, and improve running stability and reliability of the device. Through the foregoing method, a DRAM memory cell array can be fabricated, such that a memory cell array with higher current driving capability and lower electric leakage can be obtained, thereby improving data write speed and reducing power consumption.

One of the embodiments of the present disclosure further discloses a method for fabricating a multi-layer stack structure, including: fabricating a plurality of array structures by means of the method for fabricating an array structure in any one of the foregoing embodiments; and stacking the plurality of array structures in sequence from bottom to top.

For example, the array structure may be a DRAM memory array. In each layer of the DRAM memory array, the active area 20 of each memory cell is jointly formed by a low-resistance IGZO layer and a high-resistance IGZO layer. The low-resistance IGZO layer has a smooth and continuous surface with few material defects, and a high-quality homojunction interface can be formed between the low-resistance IGZO layer and the high-resistance IGZO layer, such that the on/off ratio and the threshold voltage (Vth) can be greatly improved for the transistor, and the leakage current can be reduced for the transistor, thereby reducing the heat emitted per unit area from the DRAM memory array. On this basis, multiple layers of DRAM memory arrays may be stacked to obtain the multi-layer stack structure, thereby increasing density of DRAM cells, improving storage density, and reducing power consumption.

For example, a spacer is provided between the multiple layers of array structures, and the word line structures, the bit line structures and the active areas between the multiple layers of array structures are independent of each other.

In the foregoing method for fabricating a multi-layer stack structure, fabricating the multi-layer stack structure by means of the array structure fabricated by using the foregoing method can reduce the power consumption caused by the leakage current, and reduce the heat emitted per unit area, thereby ensuring the device performance while increasing the storage density.

It is to be understood that although the steps in the flowchart of FIG. 4 are sequentially displayed as indicated by the arrows, these steps are not necessarily sequentially performed in the order indicated by the arrows. Unless expressly stated herein, the execution of these steps is not strictly restrictive and may be performed in other order. Moreover, at least a part of the steps in FIG. 4 may include a plurality of steps or a plurality of stages, which are not necessarily performed at the same moment, but may be executed at different moments, and the order of execution of these steps or stages is not necessarily performed sequentially, but may be performed alternately or alternately with at least a part of the steps or stages of other steps or other steps.

It is to be noted that the above embodiments are intended for purposes of illustration only and are not intended to limit the embodiments of the present disclosure.

The embodiments of the present disclosure are described in a progressive manner, each embodiment is focused on difference from other embodiments, and cross reference is available for identical or similar parts among different embodiments.

It should be understood that unless expressly stated herein, the execution of these steps is not strictly limited in sequence, and these steps may be performed in other orders. Moreover, at least some of the steps may include a plurality of sub-steps or a plurality of stages, which are not necessarily performed at the same moment, but may be executed at different moments, and the order of execution of these sub-steps or stages is not necessarily performed sequentially, but may be performed alternately or alternately with at least a portion of the sub-steps or stages of other steps or other steps.

Technical features of the above embodiments may be arbitrarily combined. For simplicity, all possible combinations of the technical features in the above embodiments are not described. However, as long as the combination of these technical features is not contradictory, it shall be deemed to be within the scope recorded in this specification.

The above embodiments merely express several implementations of the embodiments of the present disclosure, and descriptions thereof are relatively concrete and detailed. However, these embodiments are not thus construed as limiting the patent scope of the present disclosure. It is to be pointed out that for persons of ordinary skill in the art, some modifications and improvements may be made under the premise of not departing from a conception of the embodiments of the present disclosure, which shall be regarded as falling within the scope of protection of the embodiments of the present disclosure. Thus, patent protection scope of the embodiments of the present disclosure shall be subject to the appended claims.

What is claimed is:

1. A semiconductor structure, comprising:
a substrate having a bit line structure therein;
an active area, wherein an end of the active area is positioned on the bit line structure, and along a direction perpendicular to the substrate, the active area comprises a first channel layer and a second channel layer wrapping at least a bottom surface and part of a sidewall of the first channel layer, and a bottom of the second channel layer is electrically connected to the bit line structure;
a word line structure, wherein the word line structure is respectively positioned on two opposite sides of the active area in the direction perpendicular to the substrate; and
a source and a drain respectively positioned at two ends along an extension direction of the active area.

2. The semiconductor structure according to claim 1, wherein the first channel layer comprises a high-resistance indium gallium zinc oxide layer, and the second channel layer comprises a low-resistance indium gallium zinc oxide layer.

3. The semiconductor structure according to claim 1, wherein other end of the active area is connected to one electrode of a capacitor structure.

4. The semiconductor structure according to claim 1, wherein the word line structure comprises a gate oxide layer and a word line conductive layer positioned on an outer side of the gate oxide layer.

5. An array structure, comprising a plurality of semiconductor structures according to claim 1, the array structure having a plurality of rows and a plurality of columns, wherein
bit line structures of given ones of the plurality of semiconductor structures positioned in a same row are electrically connected to each other; and
word line structures of given ones of the plurality of semiconductor structures positioned in a same column are electrically connected to each other.

6. The array structure according to claim 5, wherein a first dielectric layer is provided between the given semiconductor structures positioned in the same column, and active areas of the given semiconductor structures in the same column are separated by the first dielectric layer; and
a second dielectric layer is provided between the given semiconductor structures positioned in the same row, and the given semiconductor structures in the same row are separated by the second dielectric layer.

7. A multi-layer stack structure, comprising multiple layers of array structures according to claim 5, wherein the multiple layers of array structures are stacked up and down, wherein
word line structures, bit line structures, and active areas in the multiple layers of array structures are independent of each other.

8. A method for fabricating an array structure, comprising:
providing a substrate;
forming a plurality of bit line structures extending along a first direction in the substrate;
forming a first dielectric layer on the substrate and forming active areas arranged in an array in the first dielectric layer, wherein an end of a given one of the active areas is positioned on the bit line structure, and in a direction perpendicular to the substrate, the given active area comprises a first channel layer and a second channel layer wrapping at least a bottom surface and part of a sidewall of the first channel layer; and a bottom of the second channel layer is electrically connected to the bit line structure;
forming a plurality of second dielectric layers extending along a second direction in the first dielectric layer, wherein the second direction intersects the first direction, and a given one of the plurality of second dielectric layers is positioned between two adjacent columns of active areas; and
forming a word line structure, wherein the word line structure is respectively positioned on two opposite sides of the given active area.

9. The method for fabricating an array structure according to claim 8, wherein the forming a plurality of bit line structures extending along a first direction in the substrate comprises:
forming multiple trenches extending along the first direction in the substrate; and
forming a conductive layer, wherein the conductive layer fills up the plurality of trenches, and an upper surface of the conductive layer is flush with an upper surface of the substrate.

10. The method for fabricating an array structure according to claim 8, wherein the forming a first dielectric layer on the substrate and forming active areas arranged in an array in the first dielectric layer comprises:
forming the first dielectric layer on an upper surface of the substrate;
forming through holes arranged in an array in the first dielectric layer, wherein a given one of the through holes is positioned above the bit line structure, and exposes an upper surface of the bit line structure; and
forming the first channel layer and the second channel layer in the given through hole, wherein the second channel layer wraps at least the bottom surface and part of the sidewall of the first channel layer, and the bottom of the second channel layer is electrically connected to the bit line structure.

11. The method for fabricating an array structure according to claim 10, wherein the forming the first channel layer and the second channel layer in the given through hole comprises:
forming the second channel layer, wherein the second channel layer covers a sidewall and a bottom of the given through hole and an upper surface of the first dielectric layer;
forming the first channel layer, wherein the first channel layer covers a surface of the second channel layer and fills up the given through hole; and
removing the first channel layer and the second channel layer on the upper surface of the first dielectric layer.

12. The method for fabricating an array structure according to claim 11, wherein the first channel layer is formed by means of an atomic layer deposition process in an oxygen-free atmosphere, and the second channel layer is formed by means of in-situ deposition in an oxygen atmosphere.

13. The method for fabricating an array structure according to claim 11, wherein the first channel layer and/or the second channel layer comprises at least one of indium oxide, gallium oxide, zinc oxide, indium gallium oxide, indium zinc oxide, gallium zinc oxide, and indium gallium zinc oxide (IGZO).

14. The method for fabricating an array structure according to claim 11, wherein the first channel layer comprises a high-resistance IGZO layer, and the second channel layer comprises a low-resistance IGZO layer.

15. The method for fabricating an array structure according to claim 8, wherein the forming multiple second dielectric layers extending along a second direction in the first dielectric layer comprises:
forming a plurality of openings extending along the second direction in the first dielectric layer, wherein a given one of the plurality of openings penetrates through the first dielectric layer and exposes an upper surface of the substrate; and
forming a given one of the plurality of second dielectric layers, wherein the given second dielectric layer fills up the given opening, and an upper surface of the given second dielectric layer is flush with an upper surface of the first dielectric layer.

16. The method for fabricating an array structure according to claim 8, wherein the forming a word line structure comprises:
reducing a thickness of the first dielectric layer to expose part of a sidewall of the given active area and part of a sidewall of the given second dielectric layer;
forming a gate oxide layer, wherein the gate oxide layer covers the exposed sidewall of the given active area;
forming a word line conductive layer on an upper surface of the first dielectric layer, wherein an upper surface of the word line conductive layer is lower than an upper surface of the gate oxide layer; and
forming the first dielectric layer on the upper surface of the word line conductive layer, wherein the upper surface of the first dielectric layer is flush with an upper surface of the given active area.

17. The method for fabricating an array structure according to claim 8, wherein after the word line structure is formed, the method further comprises:
forming a capacitor structure, wherein one electrode in the capacitor structure is connected to the other end of the given active area.

18. A method for fabricating a multi-layer stack structure, comprising:
fabricating a plurality of array structures by using the method according to claim 17; and
stacking the plurality of array structures in sequence from bottom to top.
